(19) United States
(12) Patent Application Publication
(10) Pub. No.: US 2020/0295224 A1
(43) Pub. Date: Sep. 17, 2020

(54) MANUFACTURING METHOD FOR LED DISPLAY PANEL

(71) Applicant: V TECHNOLOGY CO., LTD., Yokohama-shi (JP)

(72) Inventors: Yoshikatsu YANAGAWA, Yokohama-shi (JP); Takafumi HIRANO, Yokohama-shi (JP)

(21) Appl. No.: 16/890,942

(22) Filed: Jun. 2, 2020

Related U.S. Application Data
(63) Continuation of application No. PCT/JP2018/040958, filed on Nov. 5, 2018.

(30) Foreign Application Priority Data
Dec. 4, 2017 (JP) 2017-232743

(51) Int. Cl. H01L 33/00; H01L 33/50; H01L 25/075; H01L 27/15

(52) U.S. Cl. CPC H01L 33/0093; H01L 33/504; H01L 2933/0058; H01L 27/156; H01L 25/0753

(57) ABSTRACT

The present invention relates to a manufacturing method for an LED display panel including an LED array substrate 1 on which multiple LEDs 4 are arranged in a matrix form, and light shielding walls 3 formed on the LED array substrate 1 and surrounding the LEDs 4. The light shielding walls 3 are formed by exposing and developing a transparent photosensitive resin 16 by photolithography, to form partition walls 7, each serving as a base material of a light shielding wall 3, and then, by forming, on a surface of each partition wall 7, a thin film 8 that reflects or absorbs light emitted from an LED 4.

### BACKGROUND OF THE INVENTION

### Field of the Invention

The present invention relates to manufacturing methods for full-color light emitting diode (LED) display panels, and more particularly, relates to manufacturing methods for LED display panels preventing mixing of colors occurring between adjacent LEDs.

### Description of Related Art

A conventional full-color LED display panel is provided with: an array of micro LED devices, each emitting blue (e.g., 450 nm to 495 nm) light or deep blue (e.g., 420 nm to 450 nm) light; and an array of wavelength conversion layers (fluorescent layers) disposed over the array of the micro LED devices, each wavelength conversion layer absorbing the blue or deep blue light emitted from a corresponding micro LED device to convert the emission wavelength into the wavelength of red, green, or blue light (see, for example, JP 2016-523450 A).

However, in such a conventional LED display panel, a black matrix is used as a light shielding wall for separating wavelength conversion layers (fluorescent layers) for red, green and blue colors. Thus, when a photosensitive resin containing a black pigment is used as the black matrix in a case in which the wavelength conversion layers are thick, there is a concern that a deep portion of the resin is prevented from being exposed with light due to the light shielding performance of the black matrix, and an unexposed portion remains. Therefore, when loading a fluorescent resist containing a fluorescent colorant (pigment or dye) of the corresponding color into openings (pixels) for each color surrounded by the light shielding walls, a part of the light shielding wall may collapse, and the fluorescent resist may leak into an adjacent opening for another color. Thus, there is a concern that this may result in colors being mixed. In particular, these problems become particularly notable when the light shielding walls have great height-to-width aspect ratios.

### SUMMARY OF THE INVENTION

Thus, in view of the above problems, an object of the present invention is to provide a manufacturing method for an LED display panel preventing mixing of colors occurring between adjacent LEDs.

In order to achieve the object, according to the present invention, a manufacturing method for an LED display panel including an LED array substrate on which multiple LEDs are arranged in a matrix form, and light shielding walls formed on the LED array substrate and surrounding the LEDs, the method including, to form the light shielding walls, the steps of:

exposing and developing a transparent photosensitive resin by photolithography, to form partition walls, each configured to be a base material of a light shielding wall; and

forming, on a surface of each partition wall, a thin film that reflects or absorbs light emitted from an LED, is provided.

Furthermore, the manufacturing method for an LED display panel according to the present invention, further including the steps, after forming the light shielding walls on a transparent substrate with a release layer, of:

aligning the LED array substrate and the transparent substrate such that each LED on the LED array substrate are placed between adjacent light shielding walls;

bonding the light shielding walls to the LED array substrate by an adhesive layer; and

separating the release layer from the light shielding wall, to remove the transparent substrate.

According to the present invention, the transparent photosensitive resin is used as a resin material for the light shielding walls. Thus, even when a thick photosensitive resin is used to form light shielding walls having a great height-to-width aspect ratio, it is possible to completely expose a deep portion of the resin. Unlike a photosensitive resin containing black matrix, as in the conventional art, no unexposed portion remains. This results in an increased stability of the light shielding walls. Thus, there is no risk of collapsing a part of the light shielding walls and leaking of the fluorescent resists into adjacent openings, when loading, for example, fluorescent resists into openings surrounded by the light shielding walls. Thus, it is possible to prevent mixing of colors occurring between adjacent LEDs.

### BRIEF DESCRIPTION OF THE DRAWINGS

FIG. 1 is a plan view showing an embodiment of an LED display panel according to the present invention.

FIG. 2 is an enlarged cross-sectional view of the main part of FIG. 1.

FIGS. 3A to 3D are explanatory views illustrating a manufacturing process of an LED array substrate of the LED display panel according to the present invention.

FIGS. 4A to 4C are explanatory views illustrating a forming process of light shielding walls of the LED display panel according to the present invention.

FIGS. 5A to 5D are explanatory views illustrating an assembling process of the LED array substrate and the light shielding walls.

FIG. 6 is an explanatory view illustrating a loading process of a fluorescent colorant.

FIGS. 7A and 7B are plan views showing modifications of the light shielding walls. FIG. 7A shows a first modification, and FIG. 7B shows a second modification.

### DESCRIPTION OF PREFERRED EMBODIMENTS

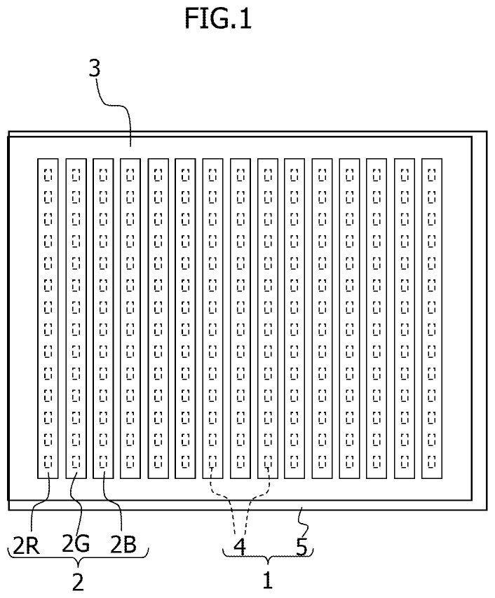

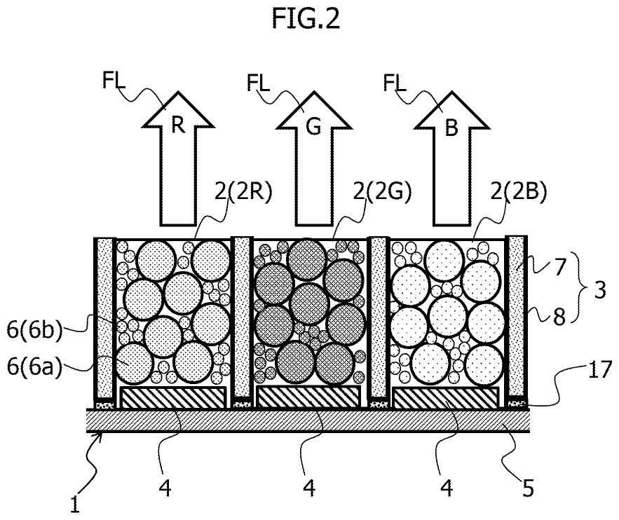

Hereinbelow, an embodiment of the present invention will be described in detail with reference to the accompanying drawings. FIG. 1 is a plan view showing an embodiment of an LED display panel according to the present invention. FIG. 2 is an enlarged cross-sectional view of the main part of FIG. 1. The LED display panel displays images in full color, and includes an LED array substrate 1, fluorescent layers 2, and light shielding walls 3.

The LED array substrate 1 is provided with multiple micro LEDs 4 (hereinafter, simply referred to as “LEDs”) arranged in a matrix form, as shown in FIG. 1. The LED array substrate 1 includes the multiple LEDs 4 arranged on a wiring board for display (“display wiring board”) 5, which includes a flexible board and a TFT drive board including wiring for supplying a drive signal to each LED 4 from a drive circuit provided externally, and for driving the LEDs 4 individually to be ON and OFF to turn the LEDs 4 on and off.

Each LED 4 emits light in an ultraviolet or blue wavelength band, and is manufactured using gallium nitride (GaN), as a main material. The LED may be an LED that emits a near-ultraviolet light having a wavelength of, for example, 200 nm to 380 nm, or may be an LED that emits a blue light having a wavelength of, for example, 380 nm to 500 nm.

On each LED 4 on the LED array substrate 1, a fluorescent layer 2 is provided, as shown in FIG. 2. The fluorescent layers 2 perform wavelength conversion by being excited by excitation light emitted from the LEDs 4 and by emitting fluorescence FL of the corresponding colors. The fluorescent layers 2 include red fluorescent layers 2R, green fluorescent layers 2G, and blue fluorescent layers 2B, which are arranged side by side on corresponding LEDs 4 in a manner corresponding to the three primary colors of light, that is, red, green and blue. Each fluorescent layer 2 is a fluorescent resist containing a fluorescent colorant 6 (pigment or dye) of a corresponding color. Although FIG. 1 shows a case in which the fluorescent layers 2 for red, green and blue colors are arranged in the form of stripes, a fluorescent layer 2 may be provided on every LED 4 individually.

Specifically, each fluorescent layer 2 is obtained by mixing and dispersing fluorescent colorants 6a having a larger particle diameter of several tens of micrometers and fluorescent colorants 6b having a smaller particle diameter of several tens of nanometers in a resist film, as shown in FIG. 2. Although the fluorescent layer 2 may include only the fluorescent colorants 6a having a larger particle diameter, this may decrease the packing efficiency of the fluorescent colorants, and thus, may increase leakage of excitation light to the display surface. On the other hand, if the fluorescent layer 2 includes only the fluorescent colorants 6b having a smaller particle diameter, there might have been a problem in that the stability, such as light stability, is reduced. Thus, by forming the fluorescent layer 2 to include a mixture of the fluorescent colorants 6a having a larger particle diameter and the fluorescent colorants 6b having a smaller particle diameter, as described above, it is possible to reduce leakage of excitation light to the display surface and improve the luminous efficiency.

In this case, for the mixing ratio of fluorescent colorants 6 having different particle diameters, it is desired to set the fluorescent colorants 6a having a larger particle diameter to be 50 to 90% by volume, and to set the fluorescent colorants 6b having a smaller particle diameter to be 10 to 50% by volume.

The light shielding wall 3 are provided on the LED array substrate 1 with an adhesive layer (second adhesive layer 17, described later) interposed therebetween such that the light shielding walls 3 surround the LEDs 4 and the corresponding fluorescent layers 2 for red, green and blue colors. The light shielding walls 3 separate the fluorescent layers 2 for red, green and blue colors. Each light shielding wall 3 includes a thin film 8 that is deposited on the surface of a partition wall 7 formed by exposing and developing a transparent photosensitive resin by photolithography, and that reflects or absorbs excitation light emitted from an LED 4 and fluorescence FL emitted from the fluorescent layer 2 excited by excitation light.

Specifically, in order to increase the packing efficiency of the fluorescent colorants 6a having a larger particle diameter in each fluorescent layer 2, the transparent photosensitive resin may be desirably a high aspect material allowing a height-to-width aspect ratio of three or more, as the partition wall 7. An example of such a high aspect material includes a permanent photoresist for the micro electronic mechanical system (MEMS), such as SU-8 3000, manufactured by Nippon Kayaku Co., Ltd.

Specifically, the thin film 8 formed on the surface of the partition wall 7 is a metal film of aluminum, an aluminum alloy, or nickel, which easily reflects excitation light. The thin film 8 is formed to a thickness capable of sufficiently blocking excitation light and fluorescence FL, such as, 0.2 μm thickness, by a known deposition technique, such as sputtering, vapor deposition and plating. Thus, excitation light transmitted through a fluorescent layer 2 to a light shielding wall 3 is reflected by the thin film 8 made of a metal film, such as aluminum, inside the fluorescent layer 2, so as to make the reflected excitation light used for light emission of the fluorescent layer 2. This results in an improved luminous efficiency of the fluorescent layer 2.

As used herein, “upside” always refers to a side of the display surface of the display panel, regardless of the installation state of the LED display panel.

Next, the manufacturing method for the LED display panel thus configured will be described.

The manufacturing method for an LED display panel according to the present invention is a manufacturing method for an LED display panel including an LED array substrate 1 on which multiple LEDs 4 are arranged in a matrix form, and light shielding walls 3 formed on the LED array substrate 1 and surrounding the LEDs 4. In the method, the light shielding walls 3 are formed by exposing and developing a transparent photosensitive resin 16 by photolithography to form partition walls 7, each configured to be a base material of a light shielding wall 3, and then by forming, on the surface of each partition wall 7, a thin film 8 that reflects or absorbs light emitted from an LED 4.

Hereinbelow, the manufacturing method for an LED display panel will be described in detail.

First, manufacturing of the LED array substrate 1 will be described. The LED array substrate 1 is manufactured by mounting the multiple LEDs 4, which emit light in the near-ultraviolet or blue wavelength band, at predetermined positions on the display wiring board 5 provided with wiring for driving the multiple LEDs 4, in an electrically connected manner with the wiring.

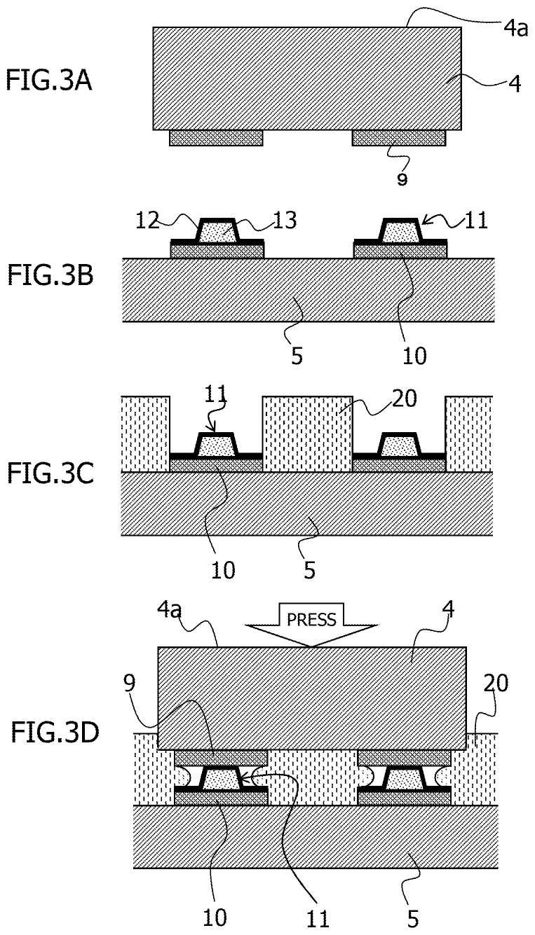

Specifically, referring to FIG. 3A, first, there are prepared multiple LEDs 4 having electrodes 9 on a side opposite the light outcoupling surface 4a, and emitting light in an ultraviolet or blue wavelength band. More specifically, the multiple LEDs 4 are provided on a sapphire substrate (not shown) and are arranged in a matrix form at the same pitch as the LED arrangement pitch on the display wiring board 5.

Next, as shown in FIG. 3B, a conductive elastic protrusion 11 is formed on each electrode pad 10 provided on the display wiring substrate 5 by patterning. In this case, the elastic protrusion 11 may be a resin protrusion 13 having a surface on which a conductive film 12 of superior conductivity, such as gold or aluminum, is deposited, or may be a protrusion 13 made of a conductive photoresist obtained by adding conductive fine particles, such as silver, to a photoresist, or be made of a conductive photoresist containing a conductive polymer.

Specifically, in a case in which the elastic protrusion 11 is a protrusion 13 having a surface on which the conductive film 12 is deposited, a resist for forming a photo spacer is applied to the entire upper surface of the display wiring board 5, and then, the resist is exposed using a photomask and is developed to form a protrusion 13 on each electrode pad 10 by patterning. Then, on the protrusions 13 and the electrode pads 10, a conductive film 12 of superior conductivity, such as gold or aluminum, is formed, by sputtering or vapor deposition, for example, to form the elastic protrusions 11.

In this case, it may be preferable, before forming the conductive film 12, to form a resist layer by photolithography on the periphery of the electrode pads 10 (i.e., except on the electrode pads 10), and after forming the conductive film 12, to dissolve the resist layer with a solution, so as to lift off the conductive film 12 on the resist layer.

Furthermore, in a case in which the elastic protrusion 11 is a protrusion 13 made of a conductive photoresist, the elastic protrusion 11 is formed by applying a conductive photoresist to the entire upper surface of the display wiring board 5 at a predetermined thickness, and then, the photoresist is exposed using a photomask and is developed to form a protrusion 13 on each electrode pad 10 by pattering.

Since the elastic protrusions 11 can thus be formed by applying such a photolithography process, it is possible to secure high precision in position and shape, and it is also possible to easily form the elastic protrusions 11 even when the distance between the electrodes 9 of the LEDs 4 is less than about 10 μm. Therefore, it is possible to manufacture a high-definition LED display panel.

Since the elastic protrusion 11 is configured to elastically deform when the LEDs 4 are pressed and the electrodes 9 of the LEDs 4 are electrically connected to the electrode pads 10 of the display wiring board 5, as described below, it is possible to reliably bring each electrode 9 of the LEDs 4 into contact with a corresponding elastic protrusion 11 even when the multiple LEDs 4 are simultaneously pressed. Thus, it is possible to reduce contact failure between the electrodes 9 of the LEDs 4 and the electrode pads 10, resulting in improved production yield of LED display panels. Herein, a case in which the elastic protrusions 11 are protrusions 13, each having the surface on which the conductive film 12 is deposited, is described.

Next, referring to FIG. 3C, a photosensitive adhesive is applied to the entire upper surface of the display wiring board 5, and then, the adhesive is exposed using a photomask and is developed to remove photosensitive adhesive applied to the electrode pads 10, so as to form a first adhesive layer 20, by patterning. In this case, the thickness of the applied photosensitive adhesive is set to be greater than a height dimension of the sum of the height of an electrode pad 10 and an elastic protrusion 11 of the display wiring board 5, and the height of a corresponding electrode 9 of the LEDs 4.

Subsequently, referring to FIG. 3D, LEDs 4 are positioned so that each electrode 9 of the LEDs 4 is arranged above a corresponding electrode pad 10 on the display wiring board 5, and then, the light outcoupling surface 4a of each LED 4 is pressed such that the electrode 9 and the electrode pad 10 are electrically connected through the conductive elastic protrusion 11. Then, the first adhesive layer 20 is cured to bond the LED 4 to the display wiring board 5. Then, the LEDs 4 are irradiated with laser light through the sapphire substrate by a known technique. This separates and removes the sapphire substrate from the LEDs 4. In this way, the mounting of the LEDs 4 on the display wiring board 5 is completed, and the LED array board 1 is thus manufactured. Here, the first adhesive layer 20 may be made of a thermosetting adhesive or an ultraviolet-curable adhesive.

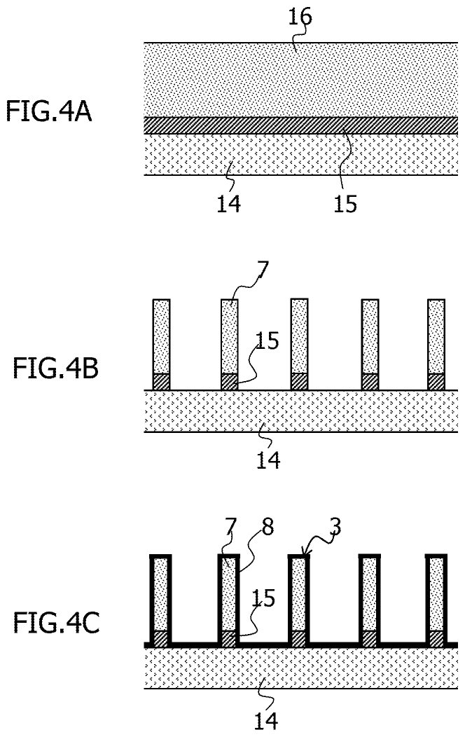

The light shielding walls 3 are formed in a separate process. Hereinbelow, a forming process of the light shielding walls will be described with reference to FIGS. 4A to 4C.

First, as shown in FIG. 4A, a transparent photosensitive resin 16 having a thickness of about 20 μm or more, preferably about 40 μm to about 50 μm, is applied to a transparent substrate 14 with a release layer 15, which functions by UV or heat, interposed therebetween. The photosensitive resin 16 used herein is a high aspect material allowing a height-to-width aspect ratio of three or more. For example, a permanent photoresist for the micro electronic mechanical system (MEMS), such as SU-8 3000, manufactured by Nippon Kayaku Co., Ltd., is suitable for the photosensitive resin 16.

Next, referring to FIG. 4B, the photosensitive resin 16 is exposed using a photomask and is developed to form partition walls 7, surrounding LEDs 4 of the same color, as shown in FIG. 1, for example, each partition wall 7 configured to be a base material for a light shielding wall 3. At this time, it may be preferable to remove release layer 15 in areas surrounded by the partition walls 7 by etching. Alternatively, the release layer 15 in the areas may be allowed to remain.

Next, referring to FIG. 4C, a thin film 8, which is a metal film of aluminum, an aluminum alloy, or nickel, for example, and which reflects or absorbs light emitted from an LED 4, specifically, excitation light emitted from an LED 4 and fluorescence FL emitted from a fluorescent layer 2 excited by excitation light, is formed on a surface of each partition wall 7, by sputtering, vapor deposition, or electroless plating, to form a light shielding wall 3. Thereby, the forming process of the light shielding walls is completed.

Thus, in a case in which the thin film 8 of the light shielding wall 3 is a metal film that reflects excitation light, excitation light transmitted through a fluorescent layer 2 to a light shielding wall 3 is reflected by the metal film, such as aluminum or nickel, inside the fluorescent layer 2, so as to make the reflected excitation light used for light emission of the fluorescent layer 2. This results in an improved luminous efficiency of the fluorescent layer 2.

Next, an assembling process of the LED array substrate 1 and the light shielding wall 3 will be described.

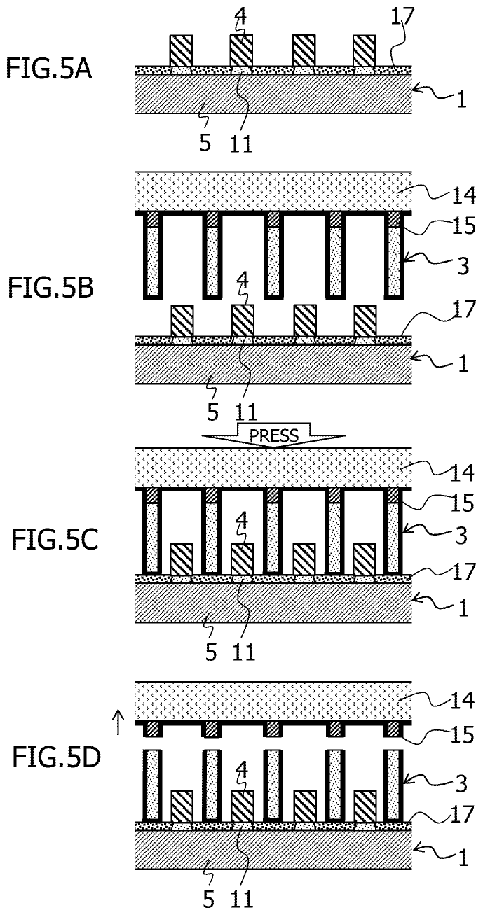

First, referring to FIG. 5A, a thermosetting adhesive or an ultraviolet-curable adhesive is applied to the LED array substrate 1 to surround the LEDs 4, to form the second adhesive layer 17. The adhesive may be applied by using a dispenser or by inkjet. Alternatively, a photosensitive adhesive may be applied to the entire surface of the LED array substrate 1, and then, the adhesive may be exposed using a photomask and be developed to form the second adhesive layer 17 on the display wiring substrate 5 to surround the LEDs 4.

Then, referring to FIG. 5B, the LED array substrate 1 and the transparent substrate 14 are aligned such that a surface of the transparent substrate 14, on which surface the light shielding walls 3 are formed, faces a surface of the LED array substrate 1, on which surface the LEDs 4 are provided, and such that each LED 4 on the LED array substrate 1 is placed between adjacent light shielding walls 3, using alignment marks (not shown) formed in advance on both the LED array substrate 1 and the transparent substrate 14.

Next, referring to FIG. 5C, in a state in which the transparent substrate 14 is pressed in the direction of the arrow, so as to bring the tip portions of light shielding walls 3 into tight contact with the second adhesive layer 17 of the LED array substrate 1, the second adhesive layer 17 is cured to bond the light shielding walls 3 to the LED array substrate 1. The second adhesive layer 17 may be cured by heat or ultraviolet light, or both heat and ultraviolet light, depending on type of adhesive used.

Subsequently, referring to FIG. 5D, the release layer 15 is heated or irradiated with ultraviolet through the transparent substrate 14, to reduce the adhesive strength (strength of tight contact) of the release layer 15, to remove the transparent substrate 14 together with the release layer 15 from the light shielding walls 3 in the direction of the arrow. Thus, the light shielding walls 3, each having the surface on which a thin film 8 is deposited, remain on the LED array substrate 1.

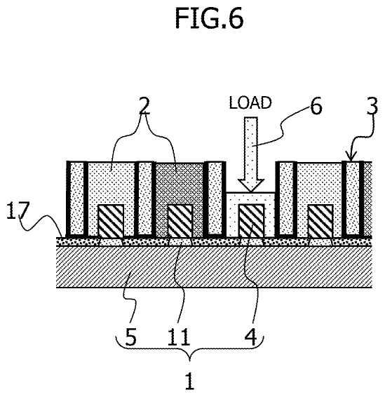

Next, as shown in FIG. 6, into an area for red, green or blue color, surrounded by light shielding walls 3, a fluorescent resist containing a fluorescent colorant 6 (pigment or dye) of a corresponding color is loaded by inkjet, for example. Then, the resist is dried to form a fluorescent layer 2. Alternatively, after applying a fluorescent resist for red, green or blue color to the entire surface of the LED array substrate 1, the fluorescent resist may be subjected to an exposing process using a photomask and a developing process, to form a fluorescent layer 2 for the corresponding color in each area for red, green or blue color, surrounded by the light shielding walls 3. An LED display panel, as shown in FIGS. 1 and 2, is thereby completed.

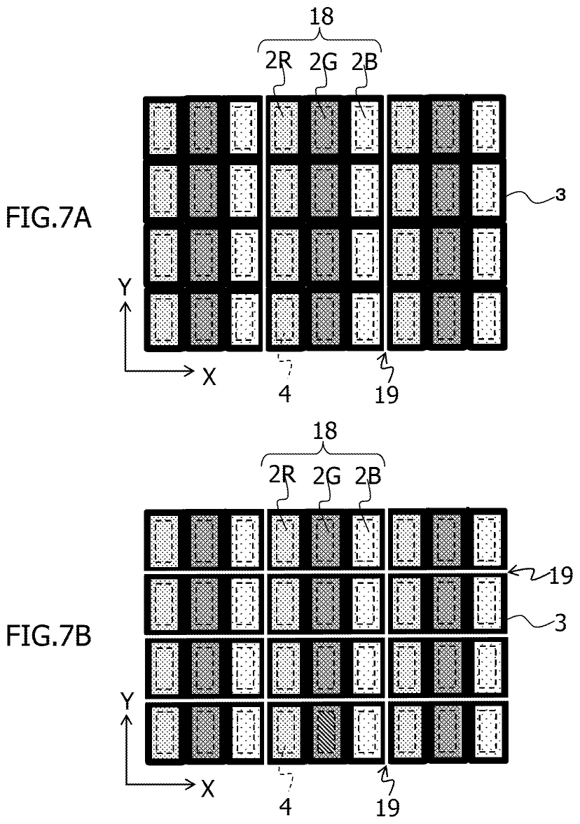

FIGS. 7A and 7B are enlarged plan views showing the main parts of modifications of the light shielding walls 3 formed in the LED display panel. FIG. 7A shows a first modification, and FIG. 7B shows a second modification.

Herein, adjacent three LEDs 4 for red, green and blue colors, and corresponding fluorescent layers 2 are regarded as one pixel 18, a first pixel arrangement direction is hereinafter referred to as “X direction”, a second pixel arrangement direction is hereinafter referred to as “Y direction”, and the X direction is orthogonal to the Y direction. In the first modification, as shown in FIG. 7A, a gap 19 intersecting with the X direction is formed in a light shielding wall 3 located between pixels 18 adjacent in the X direction.

In the second modification, as shown in FIG. 7B, a gap 19 intersecting with the X direction is formed in a light shielding wall 3 located between pixels 18 adjacent in the X direction, and a gap 19 intersecting with the Y direction is formed in a light shielding wall 3 located between pixels 18 adjacent in the Y direction.

Thus, for example, when the display wiring board 5 of the LED array substrate 1 is a flexible board, the LED display panel according to the first modification, as shown in FIG. 7A, can be easily rolled up in the X direction. Furthermore, the LED display panel according to the second modification, as shown in FIG. 7B, can be easily rolled up in either of the X direction and the Y direction. This makes the LED display panel easy to carry.

Although in the above embodiment, the light shielding walls 3 formed on the transparent substrate 14 is transferred onto the LED array substrate 1, the present invention is not limited thereto, and the light shielding walls 3 may be directly formed on the LED array substrate 1. In this case, it may be preferable that, after applying a transparent photosensitive resin 16 to the LED array substrate 1, the resin 16 be exposed using a photomask and be developed to form partition walls 7 surrounding LEDs 4, and then, a thin film 8 is formed on a surface of each partition wall 7 from the partition wall 7 side, followed by irradiation of laser light to remove the thin film 8 deposited on and around the LEDs 4.

Furthermore, in the above description, the multiple LEDs 4 are configured to emit light in the ultraviolet or blue wavelength band, and on each LED 4, there is arranged, in a manner of the three primary colors of light, a fluorescent layer 2 emitting fluorescence of red, green, or blue color, by performing wavelength conversion by being excited by excitation light emitted from the LED 4 and emitting fluorescence of a corresponding color; however, the present invention is not limited thereto, and the multiple LEDs 4 may individually emit red, green, and blue light. Alternatively, from among such LEDs 4 emitting three colors, some of the LEDs 4 may emit light in the ultraviolet or blue wavelength band and be combined with a fluorescent layer 2.

It should be noted that the entire contents of Japanese Patent Application No. 2017-232743, filed on Dec. 4, 2017, on which convention priority is claimed, is incorporated herein by reference.

It should also be understood that many modifications and variations of the described embodiments of the invention will be apparent to one of ordinary skill in the art, without departing from the spirit and scope of the present invention as claimed in the appended claims.

What is claimed is:

1. A manufacturing method for an LED display panel including an LED array substrate on which multiple LEDs are arranged in a matrix form, and light shielding walls formed on the LED array substrate and surrounding the LEDs, the method comprising, to form the light shielding walls, the steps of:
exposing and developing a transparent photosensitive resin by photolithography, to form partition walls, each configured to be a base material of a light shielding wall; and
forming, on a surface of each partition wall, a thin film that reflects or absorbs light emitted from an LED.

2. The manufacturing method for an LED display panel, according to claim 1, further comprising the steps, after forming the light shielding walls on a transparent substrate with a release layer, of:
aligning the LED array substrate and the transparent substrate such that each LED on the LED array substrate are placed between adjacent light shielding walls;
bonding the light shielding walls to the LED array substrate by an adhesive layer; and
separating the release layer from the light shielding wall, to remove the transparent substrate.

3. The manufacturing method for an LED display panel, according to claim 1, wherein
each LED emits light in an ultraviolet or blue wavelength band, and
fluorescent layers are provided on corresponding LEDs in a manner corresponding to the three primary colors of light, each fluorescent layer performs wavelength conversion by being excited by excitation light emitted from a corresponding LED and by emitting fluorescence of a corresponding color.

4. The manufacturing method for an LED display panel, according to claim 3, wherein a thin film that reflects or absorbs excitation light and fluorescent light is deposited on each light shielding wall provided to surround each LED.

5. The manufacturing method for an LED display panel, according to claim 1, wherein the photosensitive resin is a high aspect material allowing a height-to-width aspect ratio of three or more, the high aspect material capable of being subjected to patterning.

6. The manufacturing method for an LED display panel, according to claim 1, wherein when adjacent three LEDs for red, green and blue colors are regarded as one pixel, at least a light shielding wall located between pixels adjacent in a first pixel arrangement direction of the first pixel arrangement direction and a second pixel arrangement direction, which are orthogonal to each other, has a gap, intersecting with the first pixel arrangement direction, formed therein.
